(19) United States
(12) Patent Application Publication
(10) Pub. No.: US 2002/0074660 A1
(43) Pub. Date: Jun. 20, 2002

(54) Semiconductor device having a multiple layer wiring structure, wiring method, wiring device, and recording medium

(75) Inventor: Shinji Fukasawa, Kasugai (JP)

Correspondence Address: ARMSTRONG,WESTERMAN & HATTORI, LLP, 1725 K STREET, NW., SUITE 1000, WASHINGTON, DC, 20006, US

(73) Assignee: FUJITSU LIMITED, Kawasaki (JP)

(21) Appl. No.: 09/855,590

(22) Filed: May 16, 2001

(30) Foreign Application Priority Data
Dec. 15, 2000 (JP) 2000-381460

(51) Int. Cl. H01L 21/44; H01L 27/10; H01L 23/48; H01L 29/40

(52) U.S. Cl. 257/758; 257/774; 438/629; 438/639; 438/118; 438/622; 257/211; 438/128

(57) ABSTRACT

In a semiconductor device having a multiple layer wiring structure, a wiring method, a wiring device, and a recording medium, by optimizing the placement of SVIA, it is possible, for an intersection portion where a lower metal wiring layer having a width W1 and an upper metal wiring layer having a width W4 intersect with the intermediate metal layers sandwiched in between, to delete one row in the X direction and two rows in the Y direction for a total of nine SVIAs, when five SVIAs are arranged at the pitch PX in the X direction (i.e. in the transverse direction of the upper metal wiring layer) and three SVIAs are arranged at the pitch PY in the Y direction (i.e. in the transverse direction of the lower metal wiring layer) for a total of fifteen SVIAs. As a result, it is possible to secure one wiring track through which wiring is able to pass from among the three wiring tracks in the X direction and two wiring tracks through which wiring is able to pass from among the five wiring tracks in the Y direction.

### BACKGROUND OF THE INVENTION

1. Field of the Invention

The present invention relates to a semiconductor device having a multiple layer wiring structure, a wiring method, a wiring device, and a recording medium and, in particular, to a connection between metal wiring layers.

2. Description of the Related Art

Connection portions (referred to hereinafter as VIA) formed from the upper and lower metal wiring layers of intersection portions of metal wiring layers and from interlayer connecting portions that form connections between metal wiring layers, which are created using EDA tools for automatically placing and wiring in a semiconductor device, are generally formed across the entire surface of the intersection portions. As is shown in the plan view in FIG. 10 and in the cross sectional views along the lines XX′ and YY′ in FIG. 11, if the upper and lower metal wiring layers M1 and M4 are connected skipping more than one metal layer arranged between the metal wiring layers, the adjacent metal wiring layers M1 and M4 or the metal layers M2 and M3 (M1 and M2, M2 and M3, M3 and M4) are connected using VIA, and what is known as a stack VIA (referred to below as an SVIA) structure for connecting the target metal wiring layers M1 and M4 is employed. These SVIA are also arranged in a matrix formation, with the pitches of the wiring tracks T2 and T3 (the pitch in the X direction of T2=PX, the pitch in the Y direction of T3=PY) that are determined by design rules in terms of the layout, extending across the entire surface of the intersection portion 100 (having the surface area W1×W4) between the lower metal wiring layer M1 having the width W1 and the upper metal wiring layer M4 having the width W4.

Namely, as is shown in FIG. 11, the metal wiring layer M1 and the metal layer M2 are connected by an interlayer connection portion CUT 12 to form an intermediate VIA (VIA 12). Moreover, the metal layer M2 and the metal layer M3 are connected by the interlayer connection portion CUT 23 to form an intermediate VIA (VIA 23). Furthermore, the metal layer M3 and the upper metal wiring layer M4 are connected by the interlayer connection portion CUT 34 to form an intermediate VIA (VIA 34). Taken together, the whole forms an SVIA that connects the metal wiring layers M1 and M4. At this time, the metal layers M2 and M3 are placed in an area that overlaps with the intersection portion 100 of the metal wiring layers M1 and M4, and an SVIA array configuration is formed extending over the entire surface of the intersection portion 100.

Here, as a design rule in terms of the layout of the interlayer connection portions CUT 12, CUT 23, and CUT 34 in the VIA and the upper and lower metal wiring layers M1 and M4 or the metal layers M2 and M3 (these will all be referred to below as metal layers M), as is shown in FIG. 12, a margin having the width OH is set in the upper and lower metal layers M in order to ensure a sufficient leeway for position shifting generated during manufacturing for the interlayer connection portions CUT of the width CS of the smallest opening. Accordingly, from the restriction on the positional shift margin of the metal layer M and the interlayer connection portion CUT, the minimum width of the metal layer M forming the VIA is set as a design rule as:

MS(VIA)=CS+2×OH (1).

However, in the design rule in Expression (1), there are cases in which, although it is possible to ensure the positional shift margin, the restrictions pertaining to the minimum pattern surface area of a metal layer M that is necessary when processing the metal layer M are not overcome. In these cases, because the signal wiring, the power supply wiring and the like, extends out from the metal layer M for a VIA between adjacent metal layers M, the pattern surface area of the metal layer M forming the VIA fulfills the minimum surface area rules and causes no problem in terms of layout. However, in an SVIA, no signal wiring or the like extends out from intermediate metal layers M2 and M3 forming the intermediate VIA (VIA 12, VIA 23, and VIA 34). Therefore, the restrictions pertaining to the minimum pattern surface area need not only to provide a sufficient positional shift margin for the interlayer connection portions CUT 12, CUT 23, and CUT 34 and the metal layers M2 and M3, but to provide the minimum pattern surface area for the metal layers M2 and M3 that is necessary when the metal layers M2 and M3 are being processed. In a conventional EDA tool, as has been described above, it is normal to form an SVIA by providing the intermediate metal layers M2 and M3 such that they overlap with the entire area of the intersection portion 100 of the metal wiring layers M1 and M4 that need to be connected. For example, SVIA portions wired using EDA tools from the CADENCE Company or the AVANT Company have this structure.

In FIG. 13, VIA 23 is shown as an example of a single intermediate VIA of an SVIA. The area of the metal layers M2 and M3 forming the VIA 23 is set by the wiring pitches PX (X direction) and PY (Y direction) of the SVIA.

However, in the SVIA of the above described conventional technology, because the intermediate metal layers (i.e. M2 and M3 in FIG. 11) are provided such that they overlap with the entire area of the intersection portion 100 of the metal wiring layers M1 and M4 that need to be connected, the problem arises that the signal wiring and the like wired using the intermediate metal layers M2 and M3 is not able to pass through the intersection portion 100. In particular, when the metal wiring layers M1 and M4 are formed from wide wires such as those used for power supply wiring, the intersection portion 100 also ends up occupying a large surface area. The problem also arises that the signal wire tracks T2 and T3 of the metal layers M2 and M3 are blocked over the entire surface of this area making it impossible to increase the wiring efficiency. Moreover, as the degree of miniaturization and the level of integration of semiconductor devices advance and the multiplying of the number of metal layers M develops, the number of blocked signal wire tracks also increases correspondingly. Consequently, this problem becomes a factor in preventing the degree of miniaturization and the level of integration of semiconductor devices from advancing. The above is a problem that arises when the intermediate metal layers M2 and M3 are present overlapping the intersection portion 100 of the metal wiring layers M1 and M4. Furthermore, the problem is not limited to this and the same type of problem also arises when intermediate metal layers M2 and M3 are arranged in a configuration where they bridge the gap between metal wiring layers M1 and M4 that do not have an intersection portion so as to form an SVIA.

### SUMMARY OF THE INVENTION

The present invention has been conceived in order to solve the above problems in the conventional technology, and it is an aim of the present invention to provide to a semiconductor device having a multiple layer wiring structure, a wiring method, a wiring device, and a recording medium in which, by optimizing the placement of SVIA in a semiconductor device having a multiple layer wiring structure, the wiring efficiency is improved using intermediate metal layers positioned in the middle of connection metal wiring layers.

In order to achieve the above aim, one aspect of the present invention is a semiconductor device having a multiple layer wiring structure that has a stack VIA portion in which, when connecting in a connection area a connection metal layer and a layer to be connected that is removed from the connection metal layer with one or more intermediate metal layers, the layers are connected in sequence, wherein the semiconductor device having a multiple layer wiring structure is provided with: two or more partitioned intermediate metal layers that are partitioned the intermediate metal layer inside the connection area; and an intermediate metal layer wiring area that is sandwiched by the partitioned intermediate metal layers. Furthermore, in the wiring method for a semiconductor device having a multiple layer wiring structure of the present invention, the intermediate metal layers are partitioned where appropriate within the connection area, and an area sandwiched by the partitioned intermediate metal layers forms an intermediate metal layer wiring area.

In the semiconductor device having a multiple layer wiring structure, the intermediate metal layers forming the stack VIA portion are partitioned within the connection area. The area sandwiched by the partitioned intermediate metal layers forms the intermediate metal layer wiring area.

As a result, in the stack VIA portions, it is possible to partition intermediate metal layers that are connected in sequence from the connection metal layer and to create wiring formed from intermediate metal layers within the connection areas. Accordingly, there is no blocking of the wiring formed by the intermediate metal layers in the connection areas of the stack VIA portions, wiring is able to be passed through using the intermediate metal layer wiring areas sandwiched by the partitioned intermediate metal layers, and the wiring efficiency can be vastly improved.

Furthermore, the wiring method for a semiconductor device having a multiple layer wiring structure according to another aspect of the present invention is a wiring method for a semiconductor device having a multiple layer wiring structure which is for two or more metal layers and has a stack VIA portion in which, when connecting in a connection area a connection metal layer and a layer to be connected that is removed from the connection metal layer with one or more intermediate metal layers, the intermediate metal layers are connected in sequence starting from the intermediate metal layer adjacent to the connection metal layer, wherein the intermediate metal layers are partitioned within the connection area, and an area sandwiched by the partitioned intermediate metal layers forms an intermediate metal layer wiring area.

In the wiring method for a semiconductor device having a multiple layer wiring structure, the intermediate metal layers forming the stack VIA portion are partitioned within the connection area and the area sandwiched by the partitioned intermediate metal layers forms the intermediate metal layer wiring area.

As a result, in the stack VIA portions, it is possible to partition intermediate metal layers that are connected in sequence from the connection metal layer and to create wiring formed from intermediate metal layers within the connection areas. Accordingly, there is no blocking of the wiring formed by the intermediate metal layers in the connection areas of the stack VIA portions, wiring is able to be passed through using the intermediate metal layer wiring areas sandwiched by the partitioned intermediate metal layers, and the wiring efficiency can be vastly improved.

The wiring device for a semiconductor device having a multiple layer wiring according to another aspect of the present invention is provided with an automatic wiring design program in accordance with the above described wiring method.

As a result, it is possible to execute an automatic wiring design program for performing wiring design automatically using the wiring method for a semiconductor device having a multiple layer wiring structure described above.

The recording medium according to another aspect of the present invention records an automatic wiring design program for performing wiring design automatically using the wiring method for a semiconductor device having a multiple layer wiring structure described above.

As a result, the storing and supplying of the above automatic wiring design program for performing wiring design automatically using the wiring method for a semiconductor device having a multiple layer wiring structure described above is simplified.

The above and further objects and novel features of the invention will more fully appear from the following detailed description when the same is read in connection with the accompanying drawings. It is to be expressly understood, however, that the drawings are for the purpose of illustration only and are not intended to define the limits of the invention.

### BRIEF DESCRIPTION OF THE DRAWINGS

FIG. 1 is a structural view of a wiring device in one embodiment;

FIG. 2 is a plan view showing a connection between metal wiring layers in the embodiment;

FIG. 3 is a pattern view showing an intermediate VIA in the first specific example of the embodiment;

FIG. 4 is a plan view showing a connection between metal wiring layers in the first specific example of the embodiment;

FIG. 5 is a cross-sectional view showing a connection between metal wiring layers in the first specific example of the embodiment;

FIG. 6 is a plan view showing a connection between metal wiring layers in the second specific example of the embodiment;

FIG. 7 is a cross-sectional view showing a connection between metal wiring layers in the second specific example of the embodiment;

FIG. 8 is a flow chart showing a wiring method for an intermediate metal layer partitioning routine in the embodiment;

FIG. 9 is a cross-sectional view of a semiconductor device having a multiple layer wiring structure;

FIG. 10 is a plan view showing a connection between metal wiring layers in the conventional technology;

FIG. 11 is a cross-sectional view showing a connection between metal wiring layers in the conventional technology;

FIG. 12 is a view of a basic minimum pattern of a VIA; and

FIG. 13 is a pattern view showing an intermediate VIA in the conventional technology.

### DETAILED DESCRIPTION OF PREFERRED EMBODIMENTS

A detailed description will now be given of a semiconductor device having a multiple layer wiring structure, a wiring method, a wiring device, and a recording medium of the present invention using a specific embodiment with reference being made to the drawings.

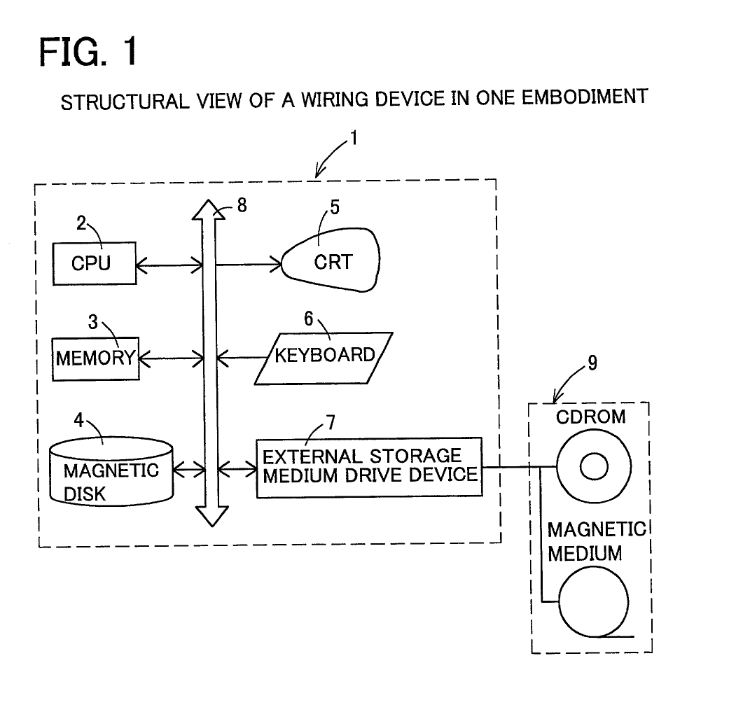

In the wiring device 1 in the semiconductor device having a multiple layer wiring structure shown in FIG. 1, memory 3, a magnetic disk device 4, a display device (abbreviated below to CRT) 5, a keyboard 6, and an external storage medium drive device 7 are mutually connected via a bus 8 centering on a central processing unit (abbreviated below to CPU) 2. In addition, an external storage medium 9 such as a CDROM or a magnetic medium is provided such that it can be attached to or removed from the external storage medium drive device 7.

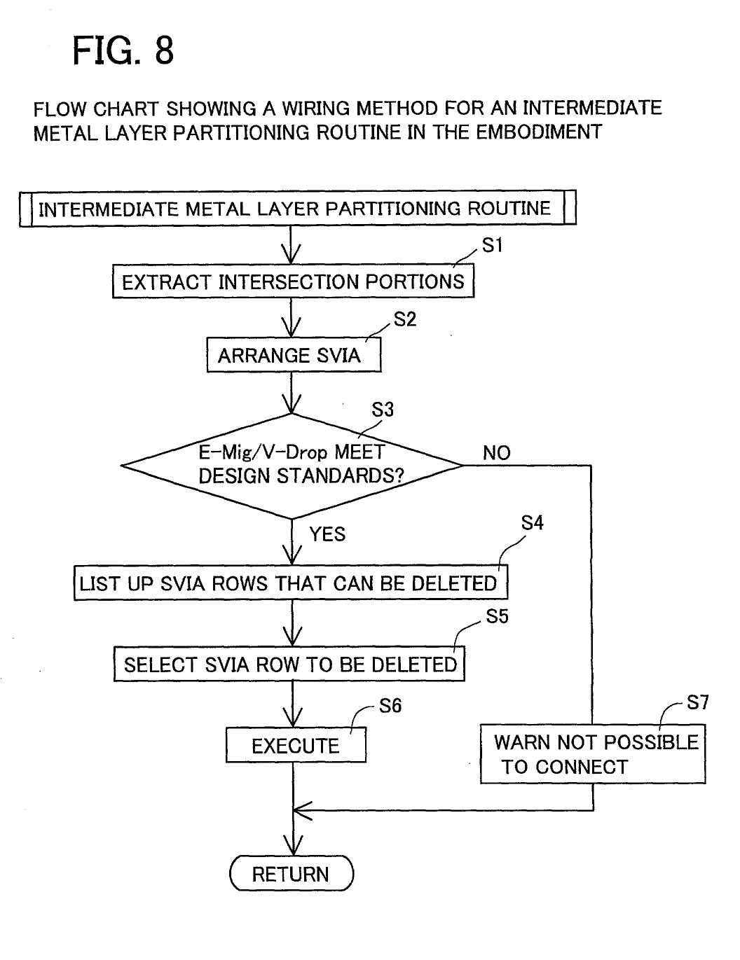

The procedure for the wiring method flow for the intermediate metal layer partitioning routine shown in FIG. 8 (described below) is recorded in the memory 3 or in the magnetic disk device 4 in the wiring device 1 in the semiconductor device having a multiple layer wiring structure. When the procedure is recorded in the external storage medium 9 such as a CDROM or a magnetic medium, the procedure is transferred to and stored in the memory 3 and the magnetic disk device 4 via the external storage medium drive device 7, or is alternatively transferred directly to the CPU 2.

In addition, a series of programs and data and the like of an EDA tool for automatic wire placement are also recorded in the magnetic disk device 4 or the external storage medium 9 such as a CDROM or a magnetic medium and are referred to when necessary in response to an instruction from the CPU 2 in accordance with the program series.

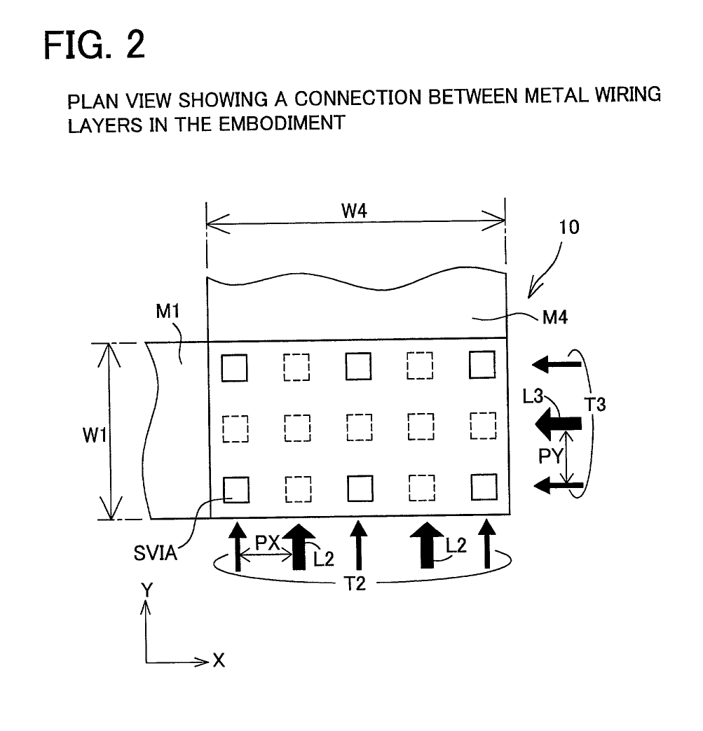

An embodiment shown in FIG. 2 shows an example of when the present invention is applied an intersection portion 10 in which the lower metal wiring layer M1 having the width W1 and the upper metal wiring layer M4 having the width W4 intersect with the intermediate metal layers M2 and M3 sandwiched in between. In this example, SVIA that have been placed in an array configuration matching the wiring tracks in the priority wiring direction of the intermediate metal layers M2 and M3 over the entire surface of the intersection portion 10 are deleted in line units.

Note that, in the embodiment described below, a case is shown in which the metal wiring layers M1 and M4 are formed as the connecting metal layers or the layers to be connected described in the first or second aspects, and in which the intermediate metal layers M2 and M3 are formed as the intermediate metal layers described in the first and second aspects.

Specifically, an example is given of when it is possible to delete one row in the X direction and two rows in the Y direction for a total of nine SVIAs, when five rows of SVIA are arranged at the pitch PX in the X direction (i.e. in the transverse direction of the upper metal wiring layer M4) and three rows of SVIA are arranged at the pitch PY in the Y direction (i.e. in the transverse direction of the lower metal wiring layer M1) for a total of fifteen SVIAs. As a result, it is possible to secure one wiring track L3 through which wiring is able to pass from among the three wiring tracks T3 in the X direction and two wiring tracks L2 through which wiring is able to pass from among the five wiring tracks T2 in the Y direction.

Here, the number of SVIA able to be deleted is decided by the value of the current flowing through the metal wiring layers M1 and M4. In other words, deletion is possible within the range of the electromigration standards that is allowable in terms of the reliability of the device decided from the current capacity of the SVIA, the value of the allowable voltage drop, and the like, and the standard of the value of the allowable voltage drop that is decided from the restrictions in terms of circuit operation. The value of the allowable resistance and the tolerable amount of electromigration that is allowable for each wire is decided from these standards and from the capacity of the current flowing through each wire. Accordingly, the number of SVIA to satisfy the allowable values is calculated from the values per single SVIA unit.

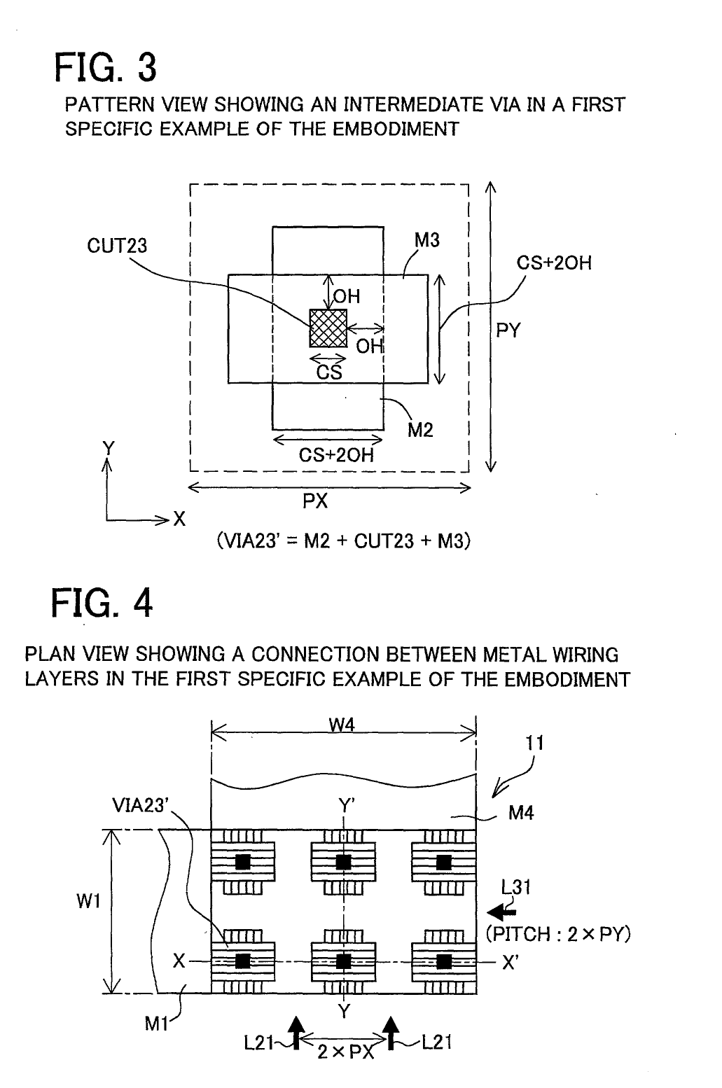

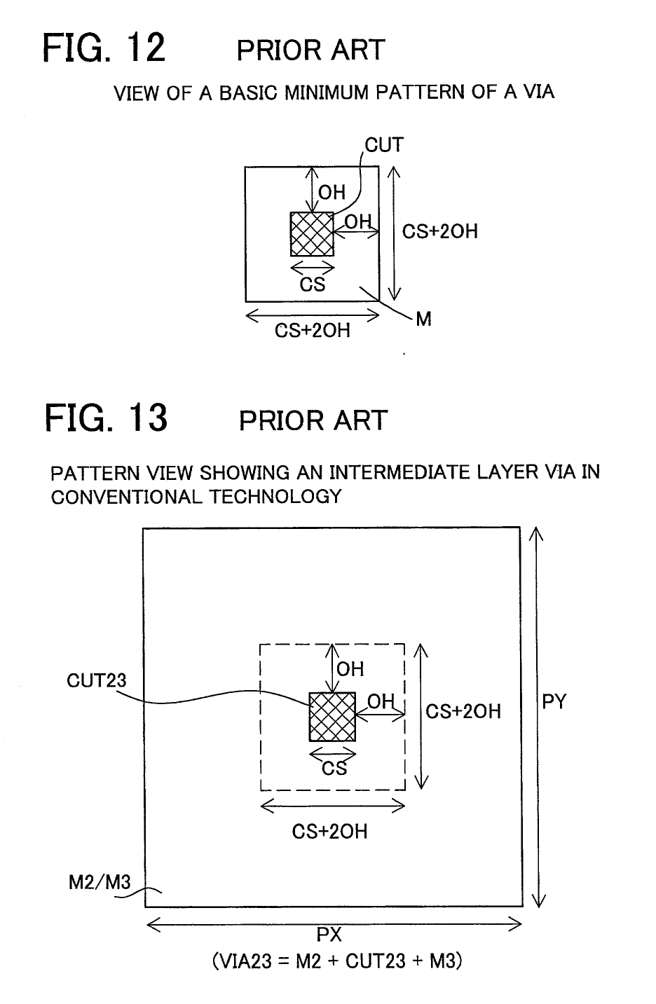

Next, a specific example will be given of when the present embodiment is actually used in an intermediate VIA specific layout pattern. FIG. 3 is a view of the layout pattern of the first specific example of an intermediate VIA 23′ formed from intermediate metal layers M2 and M3 and an interlayer connection portion CUT 23 that connects M2 and M3 together. As described above on the basis of FIG. 12, the minimum width of the metal layer M shown in Expression (1) is the minimum width needed to ensure the positional shift margin for the interlayer connection portion CUT and the metal layer M, however, it does not meet the restrictions imposed by the minimum pattern surface area that is required when the metal layer M is being processed. In FIG. 3, a method is shown for meeting these restrictions even for the intermediate metal layers M2 and M3 that do not have any outgoing wires.

When a metal layer is used as the wiring layer, it is normal to set the wiring directions for each metal wiring layer with the directions in adjacent metal wiring layers that are orthogonal to each other set as the priority wiring directions. In the present embodiment, because the priority wiring direction of the lower metal wiring layer M1 is taken as the X direction and the priority wiring direction of the upper metal wiring layer M4 is taken as the Y direction, the priority wiring direction of the intermediate metal layer M2, which is the metal layer directly above the lower metal wiring layer M1, becomes the Y direction. The priority wiring direction of the intermediate metal layer M3 above that becomes the X direction. When providing metal wiring, the wiring tracks are set in the priority wiring direction. Therefore, the wiring pitch is set in the size of the metal layer in the transverse direction relative to the priority wiring direction. Accordingly, in the intermediate VIA 23′, it is preferable if the metal layers are extended in the priority wiring directions by only the amount of the surface area that is able to secure the minimum pattern surface area of the intermediate metal layers M2 and M3. The result of this is that a structure is employed in which, for the metal layer M2, the width in the X direction remains at the minimum width while the width in the Y direction is extended, and for the metal layer M3, the width in the Y direction remains at the minimum width while the width in the X direction is extended. By employing this structure, while the metal layer width in the priority wiring direction is held to the minimum width, the metal layer width in the direction orthogonal to the priority wiring direction is extended by the minimum amount necessary.

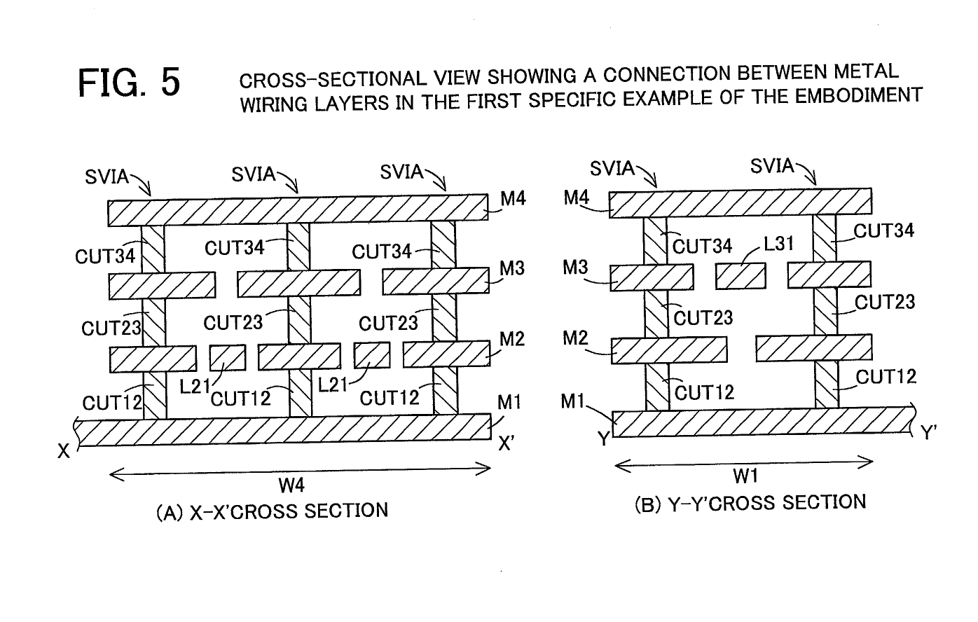

In the intersection portion 11 shown in FIG. 4, the state of the intermediate metal layers M2 and M3 when the intermediate VIA 23′ of the first specific example is placed in the intersection portion 10 in FIG. 2 is shown. In FIG. 5, the cross sections XX′ and YY′ of the intersection portion 11 are shown and the states of the intermediate metal layers M2 and M3 are shown.

In FIG. 2, one wiring track L3 in the X direction through which a wire can be passed and two wiring tracks L2 in the Y direction through which a wire can be passed are secured. Moreover, a structure is provided in which the intermediate VIA 23′ that has been put in place has the minimum width in the priority wiring direction of each of the intermediate metal layers M2 and M3. Therefore, as is clear from FIG. 4, the wiring track L31 in the X direction enables an area to be secured at a pitch of 2×PY as a wiring track having a sufficient wiring width as the through wire for the metal layer M3. The wiring tracks L21 in the Y direction enable an area to be secured at a pitch of 2×PX as wiring tracks having a sufficient wiring width as the through wire for the metal layer M2.

Because the priority wiring directions of the metal layers M2 and M3 are orthogonal to each other, as is shown in FIG. 5, for the metal layer M2, the direction orthogonal to the cross section XX′ of the intersection portion 11 becomes the priority wiring direction. The wiring tracks L21 pass through the intersection portion 11 at a pitch of 2×PX, while for the metal layer M3, the direction orthogonal to the cross section YY′ of the intersection portion 11 becomes the priority wiring direction and the wiring track L31 passes through the intersection portion 11 at a pitch of 2×PY.

In the second specific example in which the embodiment is applied to another intermediate VIA 23″ (not illustrated), the intermediate VIA 23″ is structured such that the metal layers M2 and M3 of the intermediate VIA 23′ (see FIG. 3) are extended to the pitches PY and PX of an SVIA of the conventional technology in the priority wiring directions of each of M2 and M3.

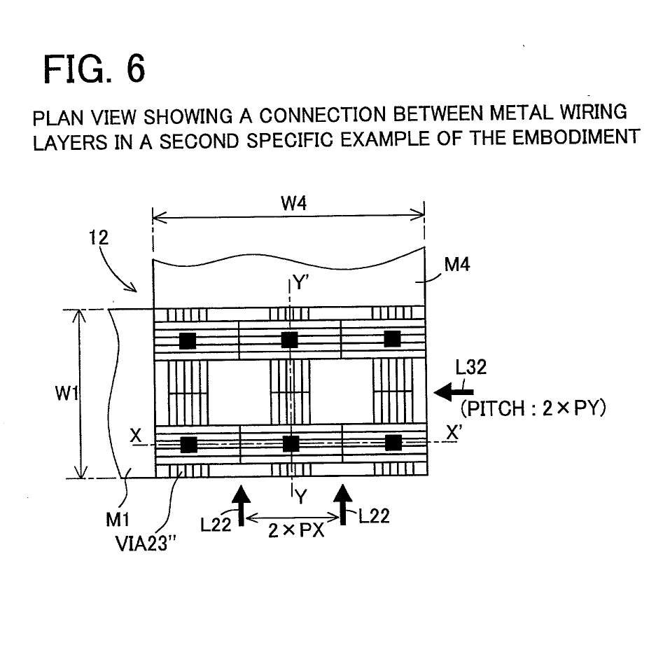

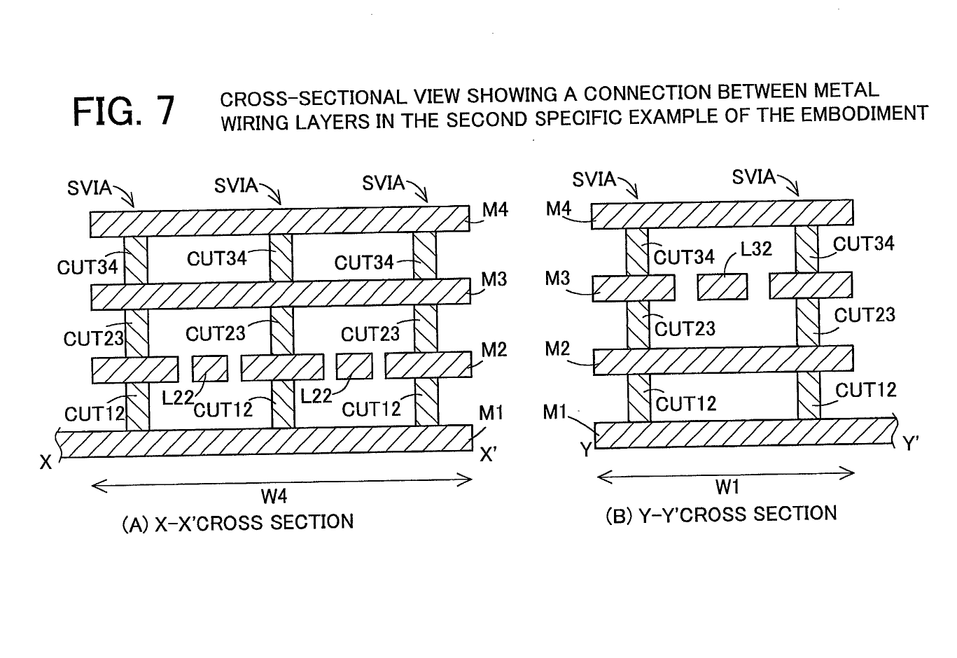

In the intersection portion 12 shown in FIG. 6, the state of the intermediate metal layers M2 and M3 is shown when the intermediate VIA 23″ is placed in the intersection portion 10 of FIG. 2. In FIG. 7, the cross sections XX′ and YY′ of the intersection portion 12 are shown and the states of the intermediate metal layers M2 and M3 are shown.

In the intermediate VIA 23″, the intermediate metal layers M2 and M3 are extended to the pitches PY and PX of the SVIA in the priority wiring directions of each. Therefore, in the intersection portion 12 in which the intermediate VIA 23″ has been placed, the intermediate metal layers M2 and M3 are structured such that they are connected to each other in the priority wiring directions of each. Namely, as is shown in FIGS. 6 and 7, the intermediate metal layers M2 and M3 are formed with each having an extended and connected structure in the YY′ direction for the metal layer M2 and in the XX′ direction for the metal layer M3.

In contrast, the transverse directions of the intermediate metal layers M2 and M3 forming the intermediate VIA 23″, in the same way as in the case shown in FIG. 3, are formed at the minimum width shown in Expression (1). Accordingly, in the same way as in the first specific example, the wiring track L32 in the X direction, as is shown in FIG. 6, enables an area for the wire to pass through to be secured at a pitch of 2×PY as a wiring track having a sufficient wiring width as the through wire for the metal layer M3. The wiring tracks L22 in the Y direction enable an area for the wires to pass through to be secured at a pitch of 2×PX as wiring tracks having a sufficient wiring width as the through wire for the metal layer M2. Moreover, as is shown in FIG. 7, in the metal layer M2, the wiring tracks L22 pass though the intersection portion 12 at a pitch of 2×PX in a direction orthogonal to the XX′ cross section of the intersection portion 12. In the metal layer M3, the wiring track L32 passes though the intersection portion 12 at a pitch of 2×PY in a direction orthogonal to the YY′ cross section of the intersection portion 12.

Next, a description will be given of the partition of the intermediate metal layer shown in FIG. 8 using the embodiment as an example. FIG. 8 shows the flow of a wiring method for an intermediate metal layer partitioning routine, and shows the intermediate metal layer partitioning routine used during the procedure of an automatic wiring design program.

Firstly, prior to beginning the routine, the layout pattern of the intermediate VIA is selected in advance (S0). In the embodiment, either the intermediate VIA 23′ or the intermediate VIA 23″ is selected. In this case, an example is given of the intermediate VIA 23′ and VIA 23″ that are necessary when the, metal wiring layers M1 and M4 are connected using an SVIA. Moreover, it is necessary to make settings in the same way for SVIA between other metal wiring layers including cases when multiple metal wiring layers are used.

In the intermediate metal layer partitioning routine, firstly, the intersection portions 10, 11, and 12 between metal wiring layers that are to be SVIA connected are extracted (S1). In the extracted intersection portions 10, 11, and 12, the SVIA are arranged in an array layout, however, it is also possible to make the procedure one in which the positions of the SVIA are arranged in an array so as to match directions running in the priority wiring directions set for the intermediate metal layers M2 and M3 of the intersection portions 10, 11, and 12. Moreover, it is also possible for the pitch of the SVIA in the array layout to be one that is matched with the wiring tracks set for the intermediate metal layers M2 and M3 of the intersection portions 10, 11, and 12 (S2). In the embodiment, this is PX for the X direction and PY for the Y direction.

With the SVIA array layout matched to the restrictions of the priority wiring directions of the intermediate metal layers M2 and M3 and the layout pitch and the like as the basic layout, a check is made as to whether or not the value of the voltage drop, the tolerable amount of electromigration in the subject SVIA portion, and the like meet the conditions of the design standards (S3). If the design standards are not already met at this point (i.e. if the determination in S3 is NO), then a warning or the like is generated to the effect that it is not possible in the subject intersection portions 10, 11, and 12 to connect M1 and M4 between the metal wiring using the SVIA (S7), and the routine is terminated. If the design standards are met (if S3 is YES), then the SVIA row that can be deleted is calculated and the list of candidates that may be deleted is updated. For example, if nine SVIAs can be deleted from among the fifteen SVIAs provided in the intersection portions 10, 11, and 12 in this embodiment, then it is possible to update the list of deletable candidates by two possible candidates, namely, one wiring track in the X direction and two wiring tracks in the Y direction (as is the case in this embodiment—see FIG. 2), or by three wiring tracks in the Y direction only. From the updated list of SVIA deletable candidates, the SVIA row to be deleted is selected (S5) in accordance with the existence or otherwise of the wiring of intermediate metal layers M2 and M3 that needs to pass through the intersection portions 10, 11, and 12 on the layout, the SVIA row is then deleted, and the layout and the like of an intermediate VIA set beforehand is performed (S6), and the current routine is ended. Note that, if an intermediate VIA is set in advance for all of the SVIA, then there is no need at this stage to perform again the layout processing for the intermediate VIA 23′ and VIA 23″. Note also that a description has been given here of an example in which all of the SVIA are deleted, however, it is also possible to selectively delete the intermediate VIA 23′ and 23″ forming the SVIA.

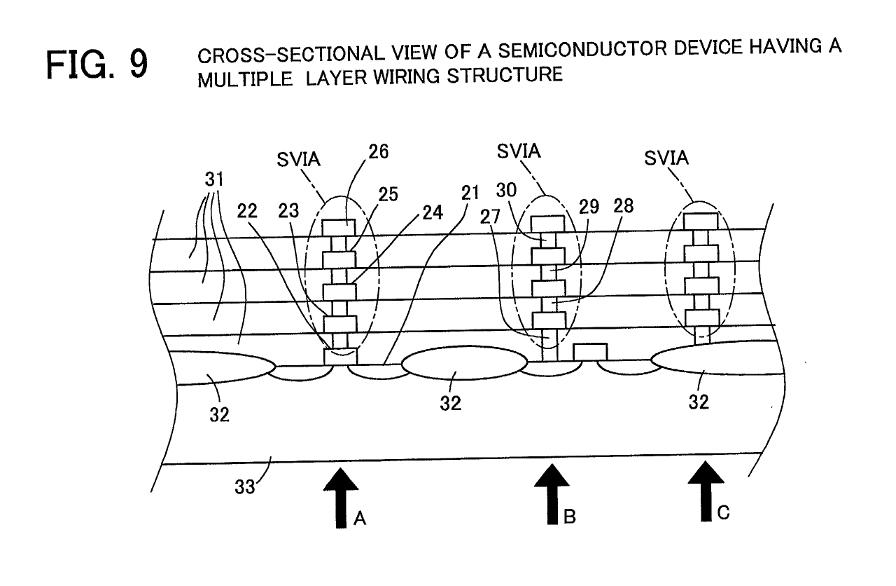

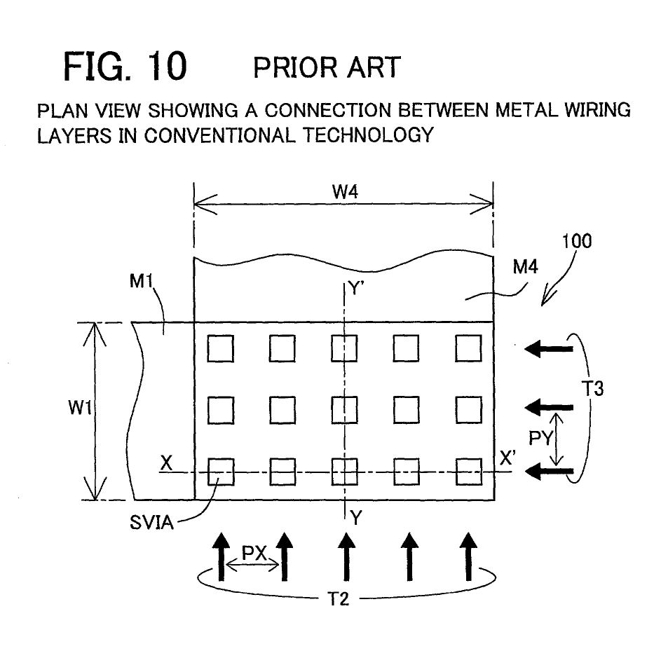

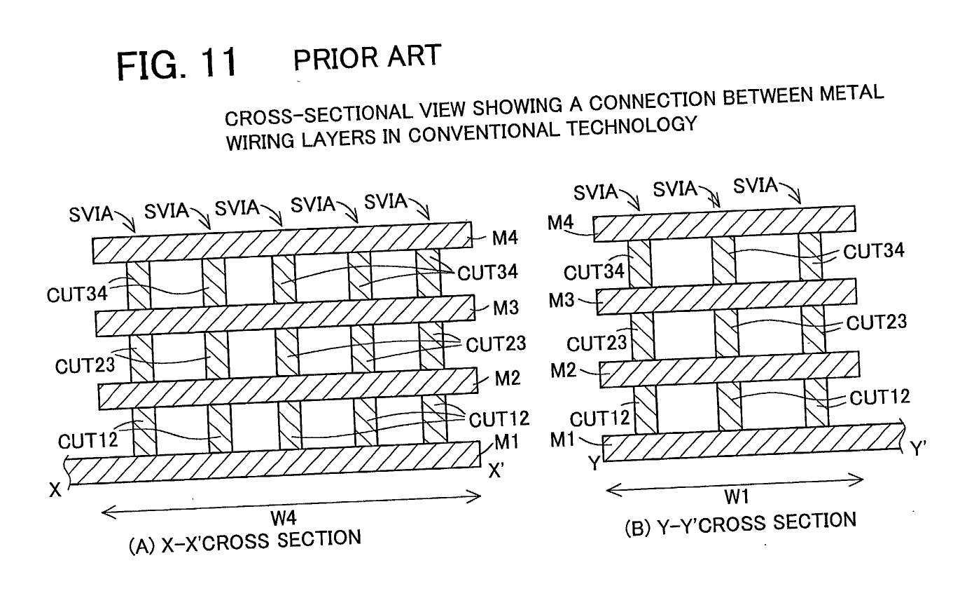

A multiple layer wiring structure to which the present invention can be applied is shown in FIG. 9. On a silicon bulk layer 33, a diffusion layer 21, a thermal oxidation film 32, and a polycrystalline silicon layer 22 that forms a MOS transistor gate electrode or the like formed on a silicon bulk layer 33 are provided. A metal wiring layer having one through four multiple layers with each layer insulated from the others by an interlayer insulation film 31. Case A is one in which an SVIA structure is formed from: the connecting metal layer described in the first or second aspects that is formed from the fourth layer metal 26; the layer to be connected described in the first or second aspects that is formed from the polycrystalline silicon layer 22; and intermediate metal layers described in the first or second aspects that are formed from three layers of metal, namely, the one through three layer metals 23, 24, and 25. Intermediate VIA are formed respectively from the first layer metal 23, the second layer metal 24 and the interlayer connecting portion CUT 12 (28) that connects the two, and from the second layer metal 24, the third layer metal 25, and the interlayer connecting portion CUT 23 (29) that connects the two. It is possible for wiring from the first through third layer metals 23, 24, and 25 to pass through the intersection portion of the fourth layer metal 26 and the polycrystalline silicon layer 22 as well.

Case B is one in which an SVIA structure is formed from: the connecting metal layer described in the first or second aspects that is formed from the fourth layer metal 26; the layer to be connected described in the first or second aspects that is formed from the diffusion layer 21; and intermediate metal layers described in the first or second aspects that are formed from three metal layers, namely, the first through third layer metals 23, 24, and 25. Intermediate VIA are formed respectively from the first layer metal 23, the second layer metal 24 and the interlayer connecting portion CUT 12 (28) that connects the two, and from the second layer metal 24, the third layer metal 25, and the interlayer connecting portion CUT 23 (29) that connects the two. It is possible for wiring from the first through third layer metals 23, 24, and 25 to pass through the intersection portion of the fourth layer metal 26 and the diffusion layer 21 as well.

Case C is one in which an SVIA structure is formed from: the connecting metal layer described in the first or second aspects that is formed from the fourth layer metal 26; the layer to be connected described in the first or second aspects that is formed from the first layer metal 23; and intermediate metal layers described in the first or second aspects that are formed from two layers of metal, namely, the second and third layer metals 24 and 25. An intermediate VIA is formed from the second layer metal 24, the third layer metal 25, and the interlayer connecting portion CUT 23 (29) that connects the two. It is possible for wiring from the second and third layer metals 24 and 25 to pass through the intersection portion of the fourth layer metal 26 and the first layer metal 23 as well.

As has been described above in detail, in the semiconductor device having a multiple layer wiring structure according to the present embodiment, in the intermediate VIA 23′ and VIA 23″, by extending the metal layers in the priority wiring direction by only the surface area that allows the minimum pattern surface area of the intermediate metal layers M2 and M3 to be secured, a structure can be employed in which, for the metal layer M2, the width in the X direction remains at the minimum width while the width in the Y direction is extended. For the metal layer M3, the width in the Y direction remains at the minimum width while the width in the X direction is extended. By employing this structure, while the metal layer width in the priority wiring direction is held to the minimum width, as is shown in the intersection portions 11 and 12, the wiring tracks L31 and L32 in the X direction enable an area to be secured at a pitch of 2×PY as wiring tracks having a sufficient wiring width to serve as the through wire for the metal layer M3. The wiring tracks L21 and L22 in the Y direction enable an area to be secured at a pitch of 2×PY as wiring tracks having a sufficient wiring width to serve as the through wire for the metal layer M2.

Accordingly, in a stack VIA portion, it becomes possible to partition intermediate metal layers M2 and M3 that are connected sequentially from the lower metal wiring layer M1 and makes possible wiring that uses the intermediate metal layers M2 and M3 of the intersection portions 10, 11, and 12 that are within the connection area. Accordingly, there is no blocking of the wiring formed by the intermediate metal layers M2 and M3 in the intersection portions 10, 11, and 12 where stack VIA portions are positioned. Wiring is able to be passed through using the wiring tracks L2, L3, L21, L31, or L22 and L32 that are intermediate metal layer wiring areas sandwiched by the partitioned intermediate metal layers M2 and M3, and the wiring efficiency can be vastly improved.

Moreover, wiring tracks L2, L3, L21, L31, or L22 and L32 that are intermediate metal layer wiring areas are formed in the same direction as the priority wiring directions set in advance in the metal wiring M2 and M3 of a semiconductor device. Accordingly, the conformity of the wiring tracks L2, L3, L21, L31, or L22 and L32 that are intermediate metal layer wiring areas passing through the stack VIA portion with the direction of the wiring formed by the intermediate metal layers M2 and M3 that are positioned as normal wires outside the stack VIA portion is excellent. There is no blocking of the wiring formed from the intermediate metal layers M2 and M3 in the intersection portions 10, 11, and 12 which are the connection areas where the stack VIA portions are positioned. Furthermore, it is also possible for the connection with external wiring to be performed smoothly and for the wiring efficiency to be vastly increased.

It is thus possible for wiring formed from the first through third layer metals 23, 24, and 25 that form the intermediate VIA positioned between the layers 26 and 22 to be passed through even in the intersection portion in the SVIA structure that connects the fourth layer metal 26 with the polycrystalline silicon layer 22. It is also possible for wiring formed from the first through third layer metals 23, 24, and 25 that form the intermediate VIA positioned between the layers 26 and 21 to be passed through even in the intersection portion in the SVIA structure that connects the fourth layer metal 26 with the diffusion layer 21. It is also possible for wiring formed from the second and third layer metals 24 and 25 that form the intermediate VIA positioned between the layers 26 and 23 to be passed through even in the intersection portion in the SVIA structure that connects the fourth layer metal 26 with the first layer metal 23.

Moreover, if the interlayer connecting portions CUT 12, CUT 23, and CUT 34 between the metal layers forming the stack VIA portions are deleted as appropriate, it is possible to secure a suitable partitioning area for the intermediate metal layers M2 and M3. Accordingly, there is no blocking of the wiring formed from the intermediate metal layers M2 and M3 in the connection areas of the stack VIA portions. Wiring is able to be passed through using the intermediate metal layer wiring areas sandwiched by the partitioned intermediate metal layers M2 and M3, and the wiring efficiency can be vastly improved.

Moreover, if the interlayer connecting portions CUT 12, CUT 23, and CUT 34 placed in an array layout to match the wiring tracks running in the priority wiring direction of the intermediate metal layers M2 and M3 are deleted as appropriate in row units in the priority wiring direction, then it is possible to secure wiring tracks in the connection area of the stack VIA portions. Accordingly, the conformity with the wiring tracks of the normal wires outside the stack VIA portion is excellent and there is no blocking of the wiring formed from the intermediate metal layers M2 and M3 in the connection area of the stack VIA portion. It is also possible for wiring to be passed through using the intermediate metal layer wiring areas sandwiched by the partitioned intermediate metal layers M2 and M3, and for the wiring efficiency to be vastly improved.

In the wiring method for a semiconductor device having a multiple layer wiring structure according to the present embodiment, the intersection portions 10, 11, and 12 between metal wiring layers that are to be SVIA connected are extracted (S1). The SVIA are then placed in a basic layout in an array configuration along the priority wiring direction set for the intermediate metal layers M2 and M3 and at the pitches PX and PY that are matched to the wiring tracks (S2). Next, the SVIA row that can be deleted is calculated and the list of candidates that may be deleted is updated (S4). The SVIA row to be deleted is then selected in accordance with the existence or otherwise of the wiring of intermediate metal layers M2 and M3 that needs to pass through the intersection portions 10, 11, and 12 on the layout (S5). The SVIA row is then deleted and it is possible to secure the wiring tracks L2, L3, L21, L31, or L22 and L32 that are the intermediate metal layer wiring areas that can pass through the intersection portions 10, 11, and 12. Note that, it is possible to achieve the same affect by deleting the interlayer connecting portion CUT 23 forming an SVIA.

As a result, if the SVIA and the interlayer connecting portion CUT 23 between the metal layers M2 and M3 are deleted where appropriate, then it is possible to partition the intermediate metal layers M2 and M3 and reliably secure the wiring tracks L2, L3, L21, L31, or L22 and L32 that are the intermediate metal layer wiring areas. Accordingly, there is no blocking of the wiring formed by the intermediate metal layers M2 and M3 in the intersection portions 10, 11, and 12 which are the connection areas of the stack VIA portions, and wiring is able to be passed through using the wiring tracks L2, L3, L21, L31, or L22 and L32 that are intermediate metal layer wiring areas sandwiched by the partitioned intermediate metal layers M2 and M3, and the wiring efficiency can be vastly improved.

In the wiring device for a semiconductor device having a multiple layer wiring structure according to the present embodiment, in a wiring device 1 for a semiconductor device having a multiple layer wiring structure, memory 3, a magnetic disk device 4, a CRT 5, a keyboard 6, and an external storage medium drive device 7 are mutually connected via a bus 8 centering on a CPU 2 and in which an external storage medium 9 such as a CDROM or a magnetic medium is provided such that it can be attached to or removed from the external storage medium drive device 7, the procedure showing the wiring method flow for the intermediate metal layer partitioning routine is, along with a series of programs and data and the like of an EDA tool for automatic wire placement, recorded in the magnetic disk device 4 or the external storage medium 9, and are referred to when necessary in response to an instruction from the CPU 2.

Accordingly, if this wiring device 1 for a semiconductor device having a multiple layer wiring structure is used, an automatic wiring design program can be executed that is capable of partitioning the intermediate metal layers M2 and M3 placed in layers on the intersection portions 10, 11, and 12 of the metal wiring layers M1 and M4 and securing an area where wiring is possible. Moreover, by recording the program on an external recording medium 9, the storing and supplying of the above automatic wiring design program is simplified.

Note that the present invention is not limited to the above embodiment, and it will be obvious that various improvements and refinements are possible without deviating from the purpose of the present invention.

For example, in the present embodiment, a description is given of when SVIA that are formed in the intersection portions 10, 11, and 12 of layers needing to be connected are deleted where appropriate and metal layers M2 and M3 positioned in the middle of the intersection portions 10, 11, and 12 are able to pass through the intersection portions 10, 11, and 12. However, the present invention is not limited to this and can also be applied in the same way in cases in which the layers to be connected are connected using intermediate VIA in a structure in which there are no intersection portions. It is also possible to form a structure in which the metal layers M2 and M3 can be passed through in the intermediate VIA portions.

According to the present invention, in a semiconductor device having a multiple layer wiring structure, by optimizing the placement of the SVIA, it is possible to provide a semiconductor device having a multiple layer wiring structure, a wiring method, a wiring device, and a recording medium that are capable of improving the wiring efficiency of intermediate metal layers positioned in the middle of connecting metal wiring layers.

What is claimed is:

1. A semiconductor device having a multiple layer wiring structure that is provided with two or more metal layers and having a stack VIA portion in which, when connecting in a connection area a connection metal layer and a layer to be connected that is removed from the connection metal layer with one or more intermediate metal layers, the intermediate metal layers are connected in sequence starting from the intermediate metal layer adjacent to the connection metal layer, wherein
the semiconductor device having a multiple layer wiring structure is provided with:
two or more partitioned intermediate metal layers that are partitioned the intermediate metal layer inside the connection area; and
an intermediate metal layer wiring area that is sandwiched by the partitioned intermediate metal layers.

2. The semiconductor device having a multiple layer wiring structure according to claim 1, wherein the connection area is an intersection portion where the connection metal layer and the layer to be connected intersect.

3. The semiconductor device having a multiple layer wiring structure according to claim 1, wherein the intermediate metal layer wiring area is formed in a priority wiring direction in the intermediate metal layer.

4. The semiconductor device having a multiple layer wiring structure according to claim 1, wherein appropriate partitioned areas of the intermediate metal layers are secured and the intermediate metal layer wiring areas are formed by deleting appropriate interlayer connection portions that connect the metal layers forming the stack VIA portion.

5. The semiconductor device having a multiple layer wiring structure according to claim 4, wherein the interlayer connection portions are arranged in an array configuration that matches wiring tracks running in the priority wiring direction in the intermediate metal layers connected to the interlayer connection portions, and are deleted where appropriate in row units running in the priority wiring direction.

6. The semiconductor device having a multiple layer wiring structure according to claim 1, wherein the partitioned intermediate metal layers are formed in accordance with minimum design rules in a transverse direction that is orthogonal to the priority wiring direction of the intermediate metal layer.

7. The semiconductor device having a multiple layer wiring structure according to claim 1, wherein the layer to be connected is a metal layer.

8. The semiconductor device having a multiple layer wiring structure according to claim 1, wherein the layer to be connected is a non-metal layer.

9. The semiconductor device having a multiple layer wiring structure according to claim 8, wherein the non-metal layer is a polycrystalline silicon layer.

10. The semiconductor device having a multiple layer wiring structure according to claim 8, wherein the non-metal layer is a diffusion layer.

11. A wiring method for a semiconductor device having a multiple layer wiring structure for two or more metal layers and a stack VIA portion in which, when connecting in a connection area a connection metal layer and a layer to be connected that is removed from the connection metal layer with one or more intermediate metal layers, the intermediate metal layers are connected in sequence starting from the intermediate metal layer adjacent to the connection metal layer, wherein
the intermediate metal layers are partitioned within the connection area, and an area sandwiched by the partitioned intermediate metal layers is formed as an intermediate metal layer wiring area.

12. The wiring method for a semiconductor device having a multiple layer wiring structure according to claim 11, wherein the connection area is formed at an intersection portion where the connection metal layer and the layer to be connected intersect.

13. The wiring method for a semiconductor device having a multiple layer wiring structure according to claim 11, wherein the intermediate metal layer wiring area is formed in the priority wiring direction in the intermediate metal layer.

14. The wiring method for a semiconductor device having a multiple layer wiring structure according to claim 11, wherein appropriate partitioned areas of the intermediate metal layers are secured and the intermediate metal layer wiring areas are formed by deleting appropriate interlayer connection portions that connect the metal layers forming the stack VIA portion.

15. The wiring method for a semiconductor device having a multiple layer wiring structure according to claim 14, wherein the interlayer connection portions are arranged in an array configuration that matches wiring tracks running in the priority wiring direction in the intermediate metal layers connected to the interlayer connection portions, and are deleted where appropriate in row units running in the priority wiring direction.

16. The wiring method for a semiconductor device having a multiple layer wiring structure according to claim 11, wherein the partitioned intermediate metal layers are formed in accordance with minimum design rules in a transverse direction that is orthogonal to the priority wiring direction of the intermediate metal layer.

17. A wiring device for a semiconductor device having a multiple layer wiring structure, wherein the wiring device is provided with an automatic wiring design program for performing wiring design automatically using the wiring method for a semiconductor device having a multiple layer wiring structure described in claim 11.

18. A recording medium on which is recorded an automatic wiring design program for performing wiring design automatically using the wiring method for a semiconductor device having a multiple layer wiring structure described in claim 11.
